(19) United States
(12) Patent Application Publication
(10) Pub. No.: US 2009/0145648 A1
(43) Pub. Date: Jun. 11, 2009

(54) MULTILAYER WIRING BOARD, MANUFACTURING METHOD THEREOF, AND SEMICONDUCTOR DEVICE

(75) Inventors: Michio HORIUCHI, Nagano (JP); Yasue TOKUTAKE, Nagano (JP); Shigeaki SUGANUMA, Nagano (JP); Naoyuki KOIZUMI, Nagano (JP); Fumimasa KATAGIRI, Nagano (JP)

Correspondence Address: DRINKER BIDDLE & REATH (DC), 1500 K STREET, N.W., SUITE 1100, WASHINGTON, DC, 20005-1209, US

(73) Assignee: SHINKO ELECTRIC INDUSTRIES CO., LTD., Nagano-shi (JP)

(21) Appl. No.: 12/323,672

(22) Filed: Nov. 26, 2008

(30) Foreign Application Priority Data
Nov. 30, 2007 (JP) P.2007-311239

(51) Int. Cl. H05K 1/18; H01R 12/06; B23K 37/00

(52) U.S. Cl. 174/260; 174/261; 228/159

(57) ABSTRACT

A multilayer wiring board is so constituted that: a group of electronic part mounting capture pads are provided on one surface thereof; a first wiring layer formed on an uppermost layer thereof includes a first connection part arranged on the same surface as the surface where the pads are provided, and a second connection part spaced from the first connection part; the pad and the first connection part are electrically connected through a conductor wire, and the conductor wire is provided in a first insulating layer laminated on the first wiring layer; and the first connection part is connected linearly or curvedly to the second connection part through a first wiring pattern.

### BACKGROUND OF THE INVENTION

The present invention relates to a multilayer wiring board; and particularly to a multilayer wiring board for mounting various kinds of electronic parts thereon, which can alleviate greatly a channel problem for a large number of I/Os of reroutes having high density, can reduce a conductor loss by alleviation of fine wiring and shortening of a wiring length, can reduce crosstalk, and can reduce and simplify a design process, and a manufacturing method of the same. The present invention relates also to a semiconductor device using such the multilayer wiring board.

In recent years, accompanying with miniaturization and a higher function of a semiconductor device, the number of electrode terminals of a semiconductor element (hereinafter referred to also as a “semiconductor chip”) mounted on the semiconductor device has increased. In order to correspond to this increase, there has been heretofore adopted a method of mounting a semiconductor chip on a wiring board by a flip-chip mounting after electrode terminals have been formed on an electrode terminal forming surface of the semiconductor chip in an area array pattern. According to the flip-chip mounting, bumps formed on the electrode terminals of the semiconductor element are connected to external connection terminals (bumps) of a wiring board, whereby the electrode terminals can be electrically connected to the external connection terminals. Further, in order to correspond to fineness of a wiring pattern, a so-called “built-up” method of using plural layers of wiring boards in a lamination form has been also adopted.

In case that the flip-chip mounting is performed in the multilayer wiring board, a basic structure is adopted in which on a side of the wiring board which receives a flip-chip bump matrix, of a pad array on its wiring board, a pad existing on the inside is pulled out, on a first layer of a uppermost layer, to the outside by guiding a wiring pattern so as to pass through a gap between the adjacent pads. When the pad is not pulled out to the outside of the bump matrix at the first layer, its pad is pulled out to a via capture pad and draw-out can be performed through its via at a layer from a second layer on. The multilayer wiring board having such the draw-out structure has been known, and a semiconductor device 90 as shown in FIG. 9 attached to this specification has been described in, for example, Patent Document 1. The shown semiconductor device 90 uses a ceramic multilayer wiring board 93 as the wiring board, above which a semiconductor element 92 is mounted by flip-chip mounting. The multilayer wiring board 93 has a bump bonding pad 96 on an element mounting surface thereof where the semiconductor element 92 is mounted, and has an external connection pad 97 on the opposite surface to the element mounting surface. On the lower surface of the semiconductor element 92, a bump 95 is disposed, and the semiconductor element 92 can be mounted on the multilayer wiring board 93 by bonding this bump 95 on the bump bonding pad 96. Further, inside the multilayer wiring board 93, a conductor wiring 98 is formed in a shown pattern. To one end portion of this conductor wiring 98, the bump bonding pad 96 is connected; and to the other end portion thereof, the external connection pad 97 is connected. To the external connection pad 97, a solder ball 94 functioning as an external connection terminal is bonded. Further, between the semiconductor element 92 and the multilayer wiring board 93, an underfill material 99 is set. However, in such the semiconductor device, there is a problem that the weight increases as the number of layers of the multilayer wiring board increases.

A semiconductor device for solving the above problem has been also described in the Patent Document 1. Namely, in the Patent Document 1, there has been described a wiring board characterized by including a sheet-shaped insulting resin; electrodes formed in predetermined positions on its insulating resin; a coated wire in which a surface of a conductor wire is coated with insulating material, and which interconnects electrically the electrodes and is partially exposed from the insulating resin; and a conductive resin formed on the insulating resin so as to seal the coated wire exposed on the insulating material. Specifically, as shown in FIG. 10 attached to this specification, a semiconductor device 100 includes a wiring board 110, a semiconductor element 112 mounted on the wiring board 110, and a solder ball 114. The wiring board 110 includes a bump bonding pad 116, an external connection pad 117, a conductive resin 122, and an insulating resin 120. Further, the semiconductor element 112 has plural bumps 115. The semiconductor element 12 is connected to the bump bonding pad 116 of the wiring board 110 by a flip-chip technology. Between the semiconductor element 112 and the wiring board 110, an underfill material 119 is buried in order to suppress occurrence of stress in the connection time. Further, between the bump bonding pad 116 and the external connection pad 117, a coated wire 118 is wire-bonded. The solder ball 114 is used to be mounted on a board 130.

In such the conventional multilayer wiring board, since a semiconductor element connecting surface and an external connection terminal forming surface are located on the same surface side, the height of the external connection terminal must be higher than at least the height of the semiconductor element. Accordingly, in case that, for example, the solder ball is used as the external connection terminal, the ball diameter increases, so that there is a problem that the connection at high density is impossible and the area of the semiconductor device increases. Further, there is also a problem that it is difficult to decrease the height of the whole of the semiconductor device.

Further, for the flip-chip mounting multilayer wiring board, it is essential to make draw-out wiring fine in accordance with decrease of a bump pitch. Specifically, accompanying with a higher function of a system, there is a tendency for the number of flip-chip I/Os to increase and for a pitch of the bumps, that is, space between the capture pads (from which wiring is drawn out) to become narrower. With this tendency, a manufacturing process of forming the wiring is becoming more difficult, which causes the decrease in yield. According to discovery of the present inventors, there is a tendency for a relation of bump pitch/capture pad diameter to change as follows: (1) 350 μm/200 μm→(2) 240 μm/110 μm→(3) 200 μm/90 μm.

Further, under such the relation of bump pitch/capture pad diameter, wiring width/wiring space necessary to draw out two pad arrays or three pad arrays is as follows respectively in the above relations (1), (2) and (3):
(1) 50 μm/50 μm (in case of two arrays), 30 μm/30 μm (in case of three arrays)
(2) 43 μm/43 μm (in case of two arrays), 26 μm/26 μm (in case of three arrays)
(3) 36 μm/36 μm (in case of two arrays), 22 μm/22 μm (in case of three arrays)

Viewed from the above tendency, it is supposed that the bump pitch becomes narrower and becomes 100 μm or less. On the other hand, since it is possible, from a viewpoint of reliability in bump connection, to make the bump pitch and the capture pad diameter too small, it is more remarkable to make the pitch narrow. For example, when the capture pad diameter is 70 μm, in order to realize one or two wirings in relation to the bump pitch 100 μm, the wiring width of 10 μm/10 μm or 6 μm/6 μm is required. However, in the conventional wiring forming technology on an organic board, it is viewed that: when the wiring width is about 10 μm, the yield starts to decrease greatly; and formation of wiring with the wiring width of 6 μm or less is impossible. In order to realize such the fine wiring, it is thought that an inorganic board such as a ceramic board or a silicon board is used in place of the organic board, and wiring is formed on its inorganic board by sputtering. However, in this case, in addition to increase in weight, increase in manufacturing cost is unavoidable. Further, even if fine wiring can be formed, a problem is produced in characteristic of the obtained fine wiring. For example, there are a problem of increase in wiring resistance accompanying with the formation of the fine wiring, and a problem of parasitic capacitance accompanying with higher dielectric constant in case that the board is the ceramic board.

### [Patent Document 1] JP-A-2000-323516 (Claims, FIGS. 1 and 5)

### SUMMARY OF THE INVENTION

An object of the invention is to provide a multilayer wiring board for mounting an electronic part, which copes with the above problems in the conventional multilayer wiring boards and can correspond to enhancements in density and functions of a system; and a manufacturing method of its multilayer wiring board. Specifically, an object of the invention is to provide a multilayer wiring board which can alleviate greatly a channel problem for a large number of I/Os of reroutes having high density, can reduce a conductor loss by alleviation of finer wiring and shortening of a wiring length, can reduce crosstalk, and can reduce and simplify a design process.

Another object of the invention is to provide a semiconductor device which uses such the multilayer wiring board and can correspond to enhancements in density and functions of a system.

These objects and another object of the invention can be readily understood from the following detailed description.

According to a first aspect of the invention, there is provided a multilayer wiring board including:

two or more layers of wiring layers and insulating layers alternately laminated, wherein

a group of electronic part mounting capture pads are provided on one surface of the multilayer wiring board;

a first wiring layer formed on an uppermost layer of the multilayer wiring board includes a first connection part arranged on the same surface as the surface where the pads are provided, and a second connection part spaced from the first connection part;

the pad and the first connection part are electrically connected through a conductor wire, the conductor wire being provided in a first insulating layer laminated on the first wiring layer; and

the first connection part is connected linearly or curvedly to the second connection part through a first wiring pattern formed on the first wiring layer.

According to a second aspect of the invention, there is provided the multilayer wiring board according to the first aspect, wherein

the second connection part is connected, through a vertical wiring part provided with penetrating the first insulating layer, to a second connection part of a second wiring layer formed under the first insulating layer.

According to a third aspect of the invention, there is provided the multilayer wiring board according to the first or second aspect, wherein

the insulating layer is formed of organic resin material having low dielectric constant.

According to a forth aspect of the invention, there is provided the multilayer wiring board according to any one of the first to third aspects, wherein

the conductor wire is formed of a wire rod of conductive metal; formed of a wire rod of conductive metal and an insulating coated layer with which the outer periphery surface of the wire rod is coated; or formed of a wire rod of conductive metal, an insulating coated layer and a conductive layer with which the outer periphery surface of the wire rod is sequentially coated.

According to a fifth aspect of the invention, there is provided a method of manufacturing the multilayer wiring board according to the first aspect, including the steps of:

preparing a metal foil for forming the electronic part mounting capture pads and the first wiring layer;

wire-bonding, by a conductor wire, a portion of the metal foil which forms the pad in a later step, and a portion of the metal foil which forms the first connection part of the first wiring layer in a later step;

applying a fluid organic insulating material onto the metal foil with thickness enough to cover the metal foil and the conductor wire throughout the entire surface thereof, and hardening the fluid organic insulating material to form a first insulating layer; and

etching the metal foil to form the pad, the first and second connection parts, and the first wiring pattern, and connecting linearly or curvedly, in this time, the first connection part and the second connection part through the first wiring pattern.

According to a sixth aspect of the invention, there is provided the manufacturing method according to the fifth aspect, further including:

a step of aligning the metal foil with a base board of the multilayer wiring board having plural wiring layers so that the first insulating layer of the metal foil is opposed to a second wiring layer on the base board, and laminating the metal foil on the base board.

According to a seventh aspect of the invention, there is provided the manufacturing method according to the sixth aspect, wherein

after the lamination step and before etching of the metal foil, an opening portion is formed in a portion of the metal foil where the second connection part of the first wiring layer is formed;

with the metal foil as a mask, the first insulating layer exposed at the opening portion is selectively etched to form a through-hole extending to the second wiring layer on the base board; and

the through-hole is filled with conductive metal, to form the vertical wiring part for connecting the second connection part of the first wiring layer and the second connection part of the second wiring layer.

According to an eighth aspect of the invention, there is provided the manufacturing method according to the fifth aspect, further including the steps of:

forming a third wiring layer on the first insulating layer; and

laminating a second insulating layer on the third wiring layer.

According to a ninth aspect of the invention, there is provided the manufacturing method according to the eighth aspect, further including:

a step of forming an insulating resin layer between the first insulating layer and the third wiring layer.

According to a tenth aspect of the invention, there is provided a semiconductor device including:

the multilayer wiring board according to the first aspect, and

electronic parts mounted on the electronic part mounting capture pads of the multilayer wiring board.

According to the invention, as understood from the following detailed description, many advantages can be obtained. For example, in the invention, the connection part is provided near to the electronic part mounting capture pad of the multilayer wiring board, for example, the flip-chip capture pad thereof; the pad and the connection part are connected by wire-bonding by use of the conductor wire (three-dimensional wire; non-plane wire) in a three-dimensional manner and a curved manner, and this conductor wire is provided in the insulating layer of the multilayer wiring board; and wiring of the sequel from the connection part is formed linearly or curvedly by the wiring pattern formed on the insulating layer. Therefore, in case that the wiring pattern is drawn out to the downside, since the vertical wiring part formed penetrating the insulating layer is utilized, the channel problem for a large number (thousands or more) of I/Os of reroutes having high density, which has existed in the conventional multilayer wiring boards, can be greatly alleviated. Further, by alleviation of finer wiring and shortening of the wiring length, a conductor loss can be reduced. For example, in the invention, compared with the case where wiring of the first insulating layer is formed by only the wire bonding, shortening of wiring length can be realized. Further, in place of the conductor wire constituted by a single wire of the conductive metal, the conductor wire having the coaxial structure is used, whereby crosstalk can be reduced. By covering the conductor wire having the coaxial structure with the conductor on its entire surface, low EMI (electromagnetic interference) can be realized. Furthermore, since the insulating layer of the multilayer wiring board is formed of the specified organic resin material having the low dielectric constant, it is possible to alleviate stress produced due to mismatch in coefficient of thermal expansion between the wiring layer and the conductor wire inside the wiring layer. Therefore, a temperature cycle life can be heightened, and the obtained multilayer wiring board can be adaptable to a high-speed device.

Further, according to the invention, it is possible to make the semiconductor element connecting surface and the external connection terminal forming surface different, and high-density mounting is possible. Therefore, even the semiconductor element of which the number of I/Os is large can be mounted without increasing the area of the semiconductor device.

In addition to these advantages, in the invention, a design process is reduced and simplified, whereby it is possible to reduce the manufacturing cost and improve reliability and yield. Further, since the connection terminal of the semiconductor element and the external connection terminal are exposed, it is possible to meet various demands of manufacturers of semiconductor devices.

### BRIEF DESCRIPTION OF THE DRAWINGS

FIG. 1 is a sectional view showing a preferred embodiment of a multilayer wiring board according to the invention.

FIG. 2 is a sectional view showing another preferred embodiment of the multilayer wiring board according to the invention.

FIG. 3 is a sectional view showing a preferred embodiment of a semiconductor device according to the invention.

FIG. 4 is a sectional view showing a wiring form of the multilayer wiring board according to the invention.

FIG. 5 is a plan view showing schematically the wiring form of the multilayer wiring board according to the invention.

FIGS. 6 (A) to 6 (G) are sectional views showing steps in a method of manufacturing the multilayer wiring board shown in FIG. 1 in order.

FIGS. 6(C′) and 6(C″) are sectional views showing a modified example of a step (C) shown in FIGS. 6(A) to 6(D).

FIGS. 7(A) to 7(D) are sectional views showing, in order, steps of manufacturing a conductor wire having the coaxial structure which can be used in the multilayer wiring board of the invention.

FIGS. 8(A) to 8(D) are sectional views showing, in order, steps of forming a vertical wiring part in the manufacturing method of the multilayer wiring board shown in FIGS. 6(E) to 6(G).

FIG. 9 is a sectional view showing an example of a conventional multilayer wiring board.

FIG. 10 is a sectional view showing another example of the conventional multilayer wiring board.

### DETAILED DESCRIPTION OF THE PREFERRED EMBODIMENTS

A multilayer wiring board, a manufacturing method thereof, and a semiconductor device according to the invention can be advantageously carried out respectively in various embodiments. Although a preferred embodiment of the invention will be described below referring to the attached drawings, the invention is not limited to the following embodiment. For example, an embodiment in which flip-chip mounting is used in order to mount an electronic part is described below, but the invention is not limited to this embodiment.

As an aspect of the invention, there is a multilayer wiring board. A multilayer wiring board of the invention, as described above, is characterized, in a flip-chip mounting multilayer wiring board in which two and more layers of wiring layers and insulating layers are alternately laminated, in that:
(1) a group of flip-chip capture pads are provided on one surface of the multilayer wiring board;
(2) a first wiring layer formed on a uppermost layer of the multilayer wiring board has a first connection part arranged on the same surface on the same where the flip-chip capture pads are provided, and a second connection part spaced from the first connection part;
(3) the flip-chip capture pad is electrically connected to the first connection part through a conductor wire, and the conductor wire is provided in a first insulating layer laminated on the first wiring layer; and
(4) the first connection part on the first wiring layer is connected through a first wiring pattern on the same first wiring layer to the second connection part linearly or curvedly.

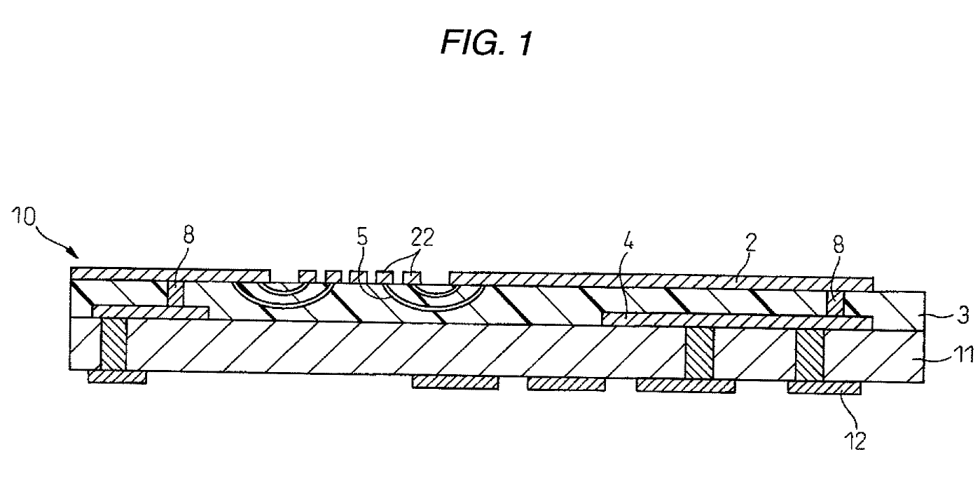

The multilayer wiring board according to the invention can has, for example, the configuration shown in FIG. 1. A shown multilayer wiring board 10, for the purpose of easy understanding of the layer configuration, includes a base board 11 of the multilayer wiring board, and an insulating layer (first insulating layer) 3 laminated on the base board 11. The shown base board 11, of which the inner structure is not described in detail, has two-layer structure. On the upper surface of the base board 11, a second wiring layer 4 is arranged; and on the lower surface thereof, connection pads 12 for connecting external parts are arranged. The second wiring layer 4 and the connection pad 12 are connected to each other through a conductor portion formed penetrating the base board 11. Further, the base board 11 is not limited to the two-layer structure but may have three-layer structure or more layer-structure.

The multilayer wiring board can has basically the similar configuration to that of the conventional multilayer wiring board generally used, except that the wiring structure between the flip-chip capture pad and the wiring layer is different. Further, in the embodiment of the invention, although the flip-chip capture pad takes a form of external connection terminals arranged in an area array pattern, it may take another form, for example, a form of one or more external connection terminals according to necessity. Further, the multilayer wiring board 10 of the invention has the lamination structure in which at least two layers of wiring layers and insulating layers are alternately laminated. The number of laminated layers of the wiring layers and the insulating layers may be two, and may three or more if necessary.

The wiring layer can be formed in an arbitrary wiring pattern by usual methods. For example, the wiring layer can be advantageously formed by selectively etching a metal foil. The metal foil used in formation of the wiring layer is not particularly limited. For example, there are conductive metal foils such as a nickel foil, a cobalt foil and a copper foil, and preferably the copper foil. Etching can be readily carried out using the ordinary etchant such as a ferric chloride etchant. The film thickness of the wiring layer, though it can be changed with a wide range, is usually about 8 to 18 μm.

Although the wiring layer can be usually formed by selective etching of the metal foil, it may be formed by another method. For example, the wiring layer may be formed by electrolytic plating with conductive metal. As an example, portions other than an area where the wiring layer is to be formed are masked with a resist, and electrolytic plating with the conductive metal such as copper (Cu) is applied with a predetermined film thickness, whereby the wiring layer can be formed.

The wiring layer can be formed adjacently to the insulating layer inside the multilayer wiring board or on the surface thereof in a predetermined wiring pattern and with a predetermined film thickness. However, in case that the wiring layer is used on the uppermost layer or the lowermost layer of the multilayer wiring board, in order to help to connect various electronic parts on its wiring layer and to connect the wiring layers to each other, an external connection terminal (generally referred to as a “connection pad”) can be formed at a predetermined portion of the wiring layer. Generally explaining the size of such the external connection terminal, in case of, for example, a circular terminal, the diameter is about 100 to 200 μm, and the thickness is about 5 to 30 μm. Further, the external connection terminal, if necessary, has on its surface a solder bump, a land, or other means in order to heighten reliability in connection, as generally performed in the field of the wiring board.

The external connection terminal (connection pad) may be formed in a single layer or in the form of a composite pad having multilayer structure of two layers or more. In case of the composite pad, for example, a first pad is formed by plating with low-melting metal, and sequentially a second pad can be formed by plating with metal of which a melting point is higher than that of the low-melting metal. The low-melting metal is used preferably in the form of an alloy. As appropriate low-melting alloys, there are, for example, a tin-lead (SnPb) alloy, a tin-silver (SnAg) alloy, a tin-copper-silver (SnCuAg) alloy, and the like. Further, in case that the composite pad type terminal is formed in the above-described manner, it is preferable that the formation of the first pad is performed under the condition where a pad area obtained by its formation becomes larger than a second pad area.

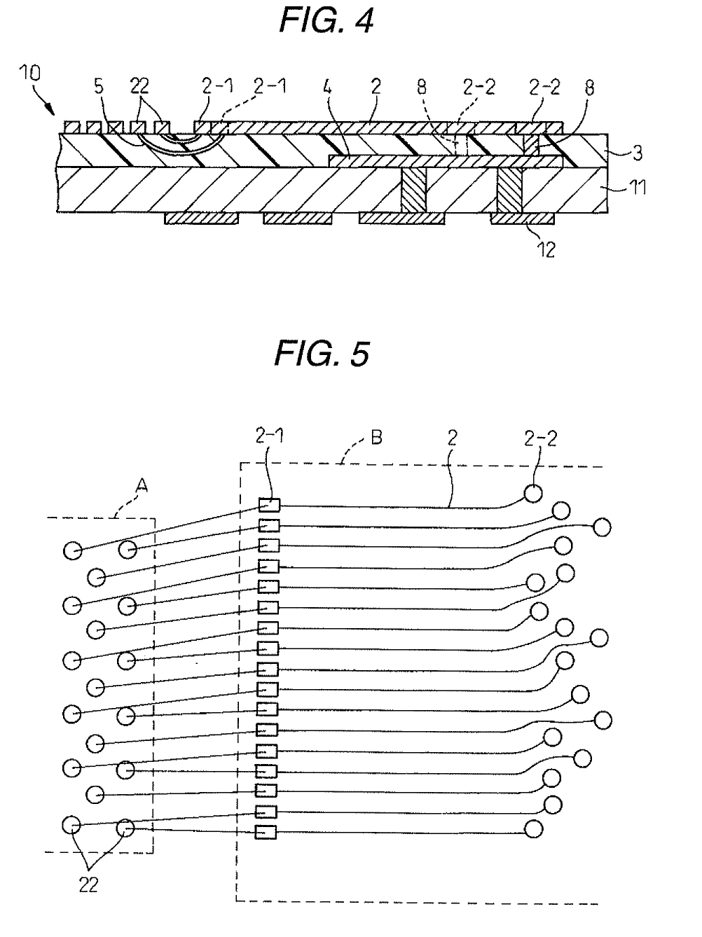

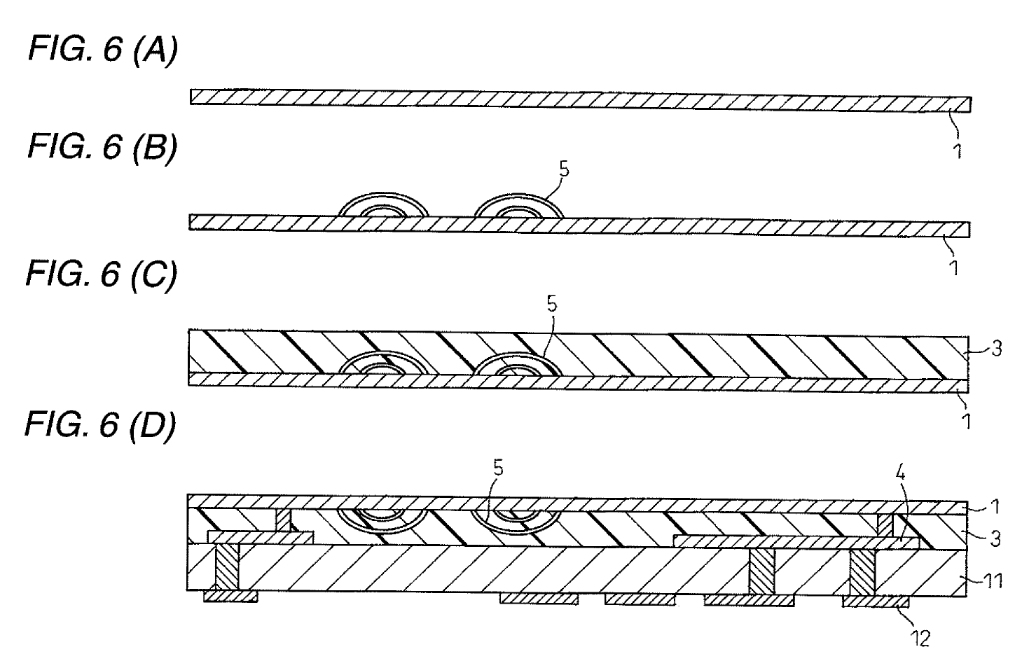

The multilayer wiring board 10 of the invention is characterized in connection of a drawing-out wire from the flip-chip capture pad to the wiring layer and in structure of the wiring layer. Referring to FIGS. 4 and 5, these connection and structure will be described. FIG. 4 is a sectional view which explains a wiring pattern of the multilayer wiring board (right half) shown in FIG. 1, and FIG. 5 is a plan view schematically showing the wiring pattern of the multilayer wiring board shown in FIG. 4.

As shown in FIG. 5, on a flip-chip mounting area A that is one surface of the multilayer wiring board 10, a group of the flip-chip capture pads 22 are provided in an area array pattern. Further, in an area adjacent to this flip-chip mounting area A, a wiring layer area B is provided extending to the vicinity of its area. Both of the flip-chip mounting area A and the wiring layer area B are formed on the insulating layer 3 in the predetermined patterns.

A first wiring layer 2 formed on the uppermost layer of the multilayer wiring board 10 is provided on the same surface as the surface where the flip-chip capture pads 22 are provided. Further, the first wiring layer 2, as shown in FIGS. 4 and 5, includes a first connection part 2-1 arranged in a position close to the flip-chip capture pad 22, and a second connection part 2-2 spaced from the first connection part 2-1.

The flip-chip capture pad 22 has a conductor wire 5 formed of conductive metal as a drawing-out wire. Further, the conductor wire 5 is electrically connected to the first connection part 2-1 of the first wiring layer 2 by wire-bonding. The first connection part 2-1 is a part of the first wiring layer 2. Since the wire-bonding method is used as connection means, as shown in FIG. 5, linear connection can be performed on a plane by the conductor wire 5, and reduction of a wiring length can be realized. Further, though the conductor wires 5 are shown in FIG. 5 so as to overlap one another, the respective conductor wires 5 are actually arranged in three dimensions and curved, so that the conductor wires 5 do not overlap one another. Further, the conductor wire 5 may have non-coaxial structure (structure having no coating), or coaxial structure (structure having coating).

The first connection part 2-1 to which the conductor wire 5 drawn out from the flip-chip capture pad 22 has been connected is electrically connected, on the first wiring layer 2 where the first connection part 2-1 is formed, to the second connection part 2-2 that is similarly a part of the first wiring layer 2. Here, the first wiring pattern for connecting the first connection part 2-1 and the second connection part 2-2 to each other, as understood from FIG. 5, is the first wiring layer 2 itself, and is a linear or curved pattern as shown in FIG. 5.

As understood from the aforesaid description of the wiring layer, the above flip-chip capture pad 22, connection parts 2-1 and 2-2, and wiring pattern 2 can be respectively formed by arbitrary methods. For example, these components may be formed by etching of a metal foil or plating with conductive metal, or may use what has been already formed as it is or after processing. Preferably, these components can be simultaneously formed in a lump by etching a metal foil such as a copper foil. Namely, by selectively etching the metal foil in accordance with the ordinary method, a part of the metal foil is removed and a part of the metal foil is formed into a thin film thereby to form the connection parts and the wiring layer (wiring pattern) 2; and simultaneously, the flip-chip capture pads (a group of external connection terminals) can be formed.

The insulating layer can be formed, similarly to the wiring layer, by the ordinary method and with the arbitrary thickness. It is preferable that the insulating layer, since the conductor wire is embedded therein, is formed of insulating organic resin, and particularly fluid organic resin. For example, by applying the selected organic resin with the predetermined thickness by a coating method or a potting method, the insulating layer can be formed. The various organic resin materials can be used in accordance with the configuration of the multilayer wiring board 10 and the desired advantages. As the appropriate organic resins, there are, for example, a silicon resin, an epoxy resin, a polyimide resin, and the like. The thickness of the insulating layer, though it is variable in a wide range, is usually within a range of about 20 to 500μ.

In the embodiment of the invention, it is particularly preferable that organic resin material having a low elastic modulus is used in formation of the insulating layer. Further, it is preferable that such the organic resin material represents usually Young's modulus of about 1 to 100 MPa. As the appropriate organic resin materials, there are, for example, a silicon resin, a modified epoxy resin, a polyimide resin, and the like. Since the organic resin material having the low elastic modulus can alleviate stress produced due to mismatch in coefficient of thermal expansion between the wiring layer and the conductor wire embedded in the insulating layer, a temperature cycle life can be heightened, and the obtained multilayer wiring board can be adaptable to a high-speed device.

Turning to FIG. 1, in the multilayer wiring board 10 of the invention, the first wiring layer 2 on the insulating layer (hereinafter, referred to as a “first insulating layer”) 3 and the second wiring layer 4 on the base board 11 are connected through a through-conductor (in the invention, this portion is particularly referred to as a “vertical wiring part”) penetrating the insulating layer 3. A vertical wiring part 8 can be formed by, for example, boring the insulating layer 3 by laser drilling and thereafter filling the obtained through-hole with conductive metal by plating. Alternatively, by inserting a pillar (post) formed of conductive metal into a through-hole, the vertical wiring part may be formed.

Here, the vertical wiring part 8 formed by penetrating the first insulating layer 3 will be further described in detail. The vertical wiring part is preferably formed of conductive metal. The vertical wiring part, in the embodiment of the invention, can be formed by various methods. For example, after a through-hole penetrating the first insulating layer enveloping the wire has been formed, its through-hole is filled with conductive metal plating, whereby the vertical wiring part for connecting the wiring layers (connection parts) to each other can be formed. The through-hole provided in the first insulating layer enveloping the wire may be provided, from the opposite surface to the pad forming surface, in the second wiring layer by laser processing. Further, a step of forming the through-hole may be performed before the etching step of the metal foil such as a copper foil. Alternatively, in place of the conductive metal plating, a pillar (post) of conductive metal having the shape and size corresponding to those of the conductive metal plating is disposed in an arbitrary stage in the multilayer wiring board formation, whereby the vertical wiring part can be formed.

More detailedly describing, for example, in case that the vertical wiring part is formed by the plating with the conductive metal, the formation can be executed generally by plating the through-hole penetrating the insulating layer with the conductive metal. Specifically, after the whole of the insulating layer surface has been coated with a resist, the resist is removed from a portion in which the vertical wiring part is to be formed. Next, with the remaining resist as a mask, the insulating layer of the base is selectively removed. The through-hole is thus formed in the insulating layer, and thereafter the conductive metal is filled into the through-hole. This filling step can be readily executed by, with the resist as the mask, electrolytic plating with the conductive metal for forming the vertical wiring part such as gold, palladium, cobalt, or nickel with a predetermined thickness. Next, the resist used as the mask is removed, whereby the vertical wiring part of the object can be obtained. Further, in the invention, in place of the resist mask, the metal foil after patterning can be used as the mask to form the desired vertical wiring part, which is preferable.

In case that the vertical wiring part is formed by the metal pole, the formation is performed generally by arranging the conductor wire on the metal foil for forming the wiring layer, and thereafter providing, in the predetermined position of its metal foil, a pillar formed of the conductive metal (so-called metal pillar) in the shape of a post. Here, as the metal pillar, there is a column, a square pillar or the like. However, if occasion arises, the metal pillar may be a broad conductor wire. The formation of the metal pillar can be performed by this method in accordance with various techniques. For example, by embedding the metal pillar, or by filling the conductive metal adapted to form the metal pillar or plating with such the conductive metal, the metal pillar can be formed. More specifically, the formation of such the metal pillar can be performed by means of methods described in JP-A-8-78581, JP-A-9-331133, JP-A-9-331134, JP-A-10-41435, and the like.

The multilayer wiring board 10 of the invention is also characterized in that the conductor wire 5 is used as the drawing-out wire from the flip-chip capture pad 22 as shown in FIG. 4. The conductor wire 5, after being drawn out from the flip-chip capture pad 22, is connected to the first connection part 2-1 of the wiring layer 2 led to a distance close to the pad 22. The conductor wire 5, as shown in FIG. 4, is curved in the insulating layer 3 in three dimensions and connected to the first wiring layer 2 of the multilayer wiring board 10. The conductor wire 5 can be, for example, formed of a wire rod of conductive metal; formed of a wire rod of conductive metal and an insulating coated layer with which the outer periphery surface of the wire rod is coated; or formed of a wire rod of conductive metal, and an insulating coated layer and a conductive layer with which the outer periphery surface of the wire rod is sequentially coated. Further, when the conductor wire 5 has the conductive layer, it is preferable that its conductive layer is connected to a ground layer of the multilayer wiring board. Although the conductor wire 5 is used in connection between the flip-chip capture pad 22 and the first wiring layer 2 in the figure, the flip-chip capture pad 22 and another portion of the multilayer wiring board 10 may be connected through the conductor wire 5 according to necessity.

In the embodiment of the invention, the conductor wire can use what is generally used as a bonding wire in a field of a semiconductor device. For example, the conductor wire may, as described above, have either the non-coaxial structure or the coaxial structure. However, it is preferable that the bonding wire used in the invention, considering that it is enclosed in the insulating organic resin material constituting the insulating layer thereby to be stably fixed, is adapted for its consideration. For example, the conductor wire can be formed of the arbitrary conductive material (conductor), and preferably a wire rod of conductive metal. As the appropriate conductive metals, there are, for example, gold, silver, copper, nickel, aluminum, or its alloy.

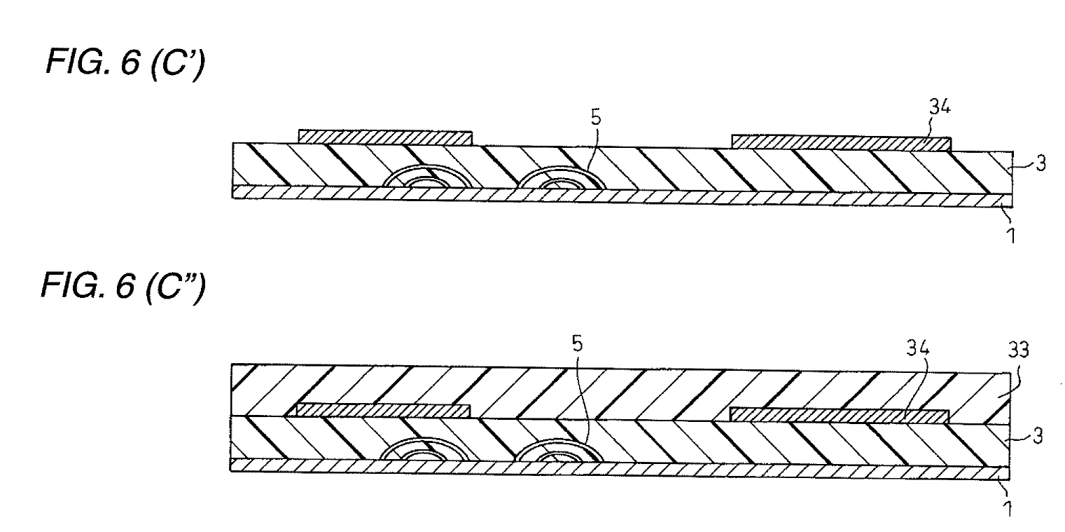

Further, it is preferable in order to avoid particularly occurrence of crosstalk that the surface of the conductor wire is coated through an insulating coated layer with a conductor layer, and preferably with a conductive metal layer, and the conductor wire has the coaxial structure having the conductor wire as a core. Namely, as shown in FIG. 7(D) which is a sectional view taken along a line D-D of FIG. 7(C), the conductor wire is advantage to have the coaxial structure in which the conductor wire 5 is coated sequentially with an insulating coated layer 14 and a conductive metal layer 15. The core of the conductor wire having this coaxial structure, as described above, can be advantageously formed by a wire rod of the conductive metal such as gold, silver, copper, nickel, aluminum, or its alloy. Further, the insulating coated layer with which such the conductor wire is coated is preferably coating of insulating resin, for example, coating of epoxy resin, polyimide resin, or the like. Further, in case of an aluminum wire, an oxide film is also effective. The resin coating can be formed by, for example, electrophotographic coating, spray coating, a dip coating, or the like. Further, in place of coating the conductor wire with the insulating coated layer, a conductor wire on the market on which the insulation coating has been already formed may be used. The conductive metal layer of the uppermost layer can be formed of the conductive metal such as gold, silver, copper, nickel, aluminum, or its alloy. Particularly, as the conductive metal, the copper can be advantageously used. The copper layer can be suitably formed by, for example, electroless copper plating or electrolytic copper plating. Preferably, the conductive metal layer is electrically connected to a ground layer (ground potential).

The conductor wire can have various sizes in its components and material. For example, in case that the conductor wire has the coaxial structure, the diameter of the core of the conductor wire is usually about 20 to 40 μm. Further, the thickness of the insulating coated layer with which the core is coated, if a conductor wire of which the periphery has been previously coated with the insulating coated layer is used and wire-bonding is performed by means of its conductor wire as it is, is usually about 2 to 8 μm. Further, in case that wire-bonding is performed by means of a non-coated conductor wire and thereafter the periphery of its conductor wire is coated with the insulating coated layer, the thickness of the insulating coated layer is usually about 10 to 50 μm. This thickness of the insulating coated layer will be varied according to the material used for the insulating coated layer and a demand of impedance matching. Further, in the multilayer wiring board of the invention, it is also possible to let the obtained multilayer wiring board have capacitance by adjusting the material (specific inductive capacity) and the thickness of this insulating coated layer according to even balance with the insulating organic resin material surrounding the conductor wire. If necessary, the conductive metal layer with which the insulating coated layer is coated can, similarly to the insulating coated layer, also change its thickness within a wide range according to the desired advantages. The thickness of the conductive metal layer is usually about 5 to 30 μm.

Turning to FIG. 7 (D), it is preferable that a ratio of an inner diameter D₀ of the metal layer 15 to an outer diameter D₁ of the conductor wire 5 is, in the conductor wire having the coaxial structure, within a range of about 1:3˜6. By such the constitution, in addition to prevention of occurrence of the crosstalk, the impedance matching can be more effectively performed.

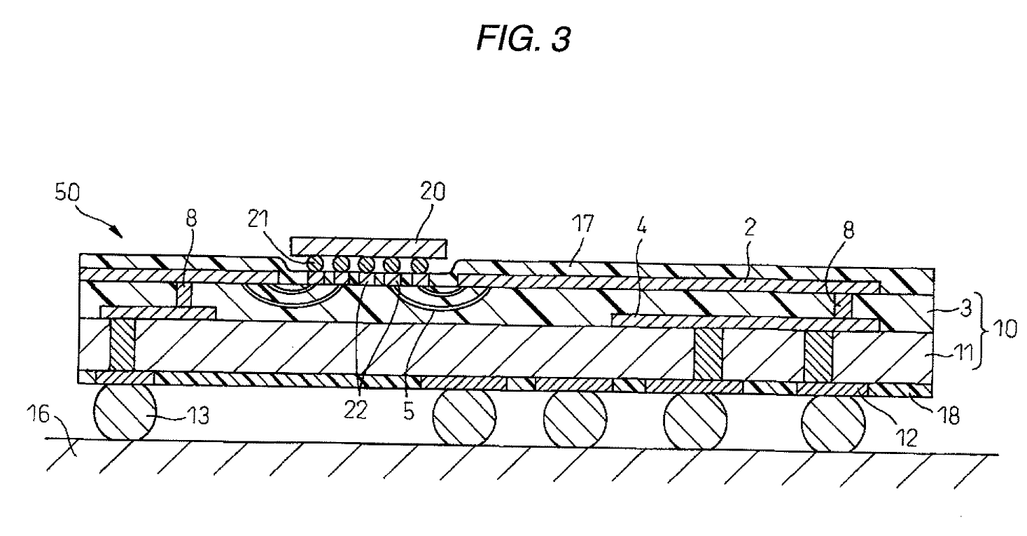

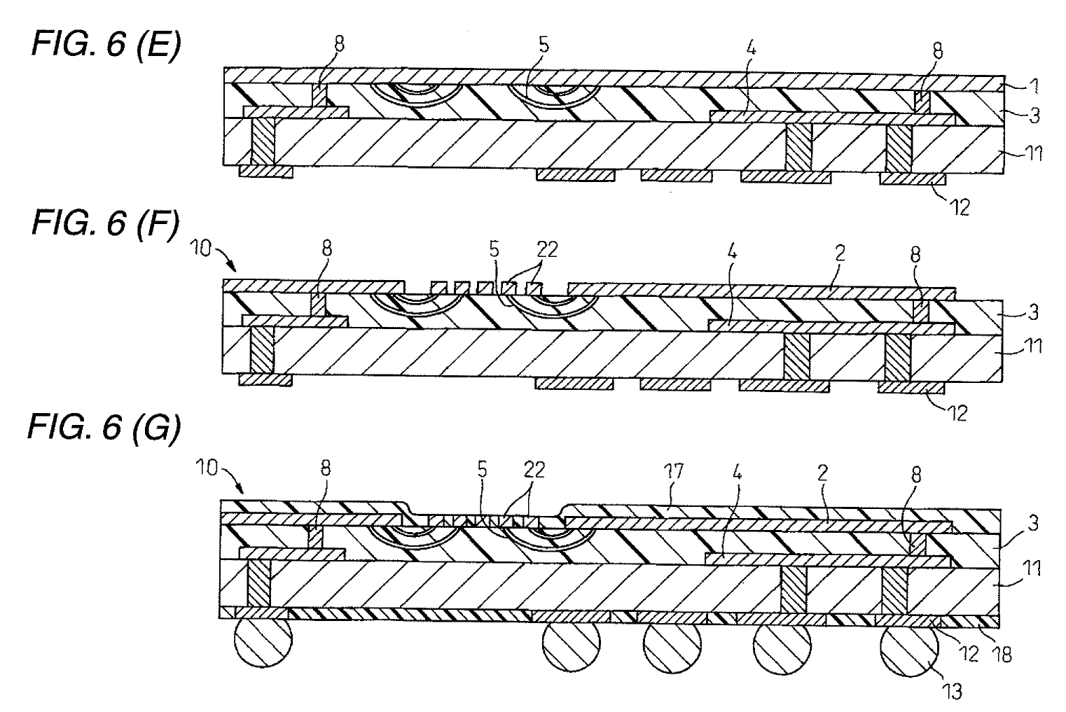

In the multilayer wiring board of the invention, the base board 11 to which the above insulating layer 3 is pasted can be an ordinary base board in the multilayer wiring board, and is not particularly limited. The base board 11 is formed of inorganic insulating material such as ceramic material or plastic material. Further, the base board 11 may use organic insulating material in place of the inorganic insulating material. Into the base board 1, wiring is built, which is not shown. On the surface of the base board 11, as shown in FIG. 1, the second wiring layer 4 is formed. The second wiring layer 4 includes electrodes, wiring, and external connection terminals of the base board 11. The second wiring layer 4 has the similar constitution to that of the first wiring layer 2 which has been already described, and can be formed by the similar method. Further, on a rear surface of the base board 11, the connection pad 12 is formed as the external connection terminal. Further, to the connection pad 12, for the purpose of connection with the external parts, a solder bump or the like can be attached. In FIGS. 3 and 6(G), a solder bump 13 is shown.

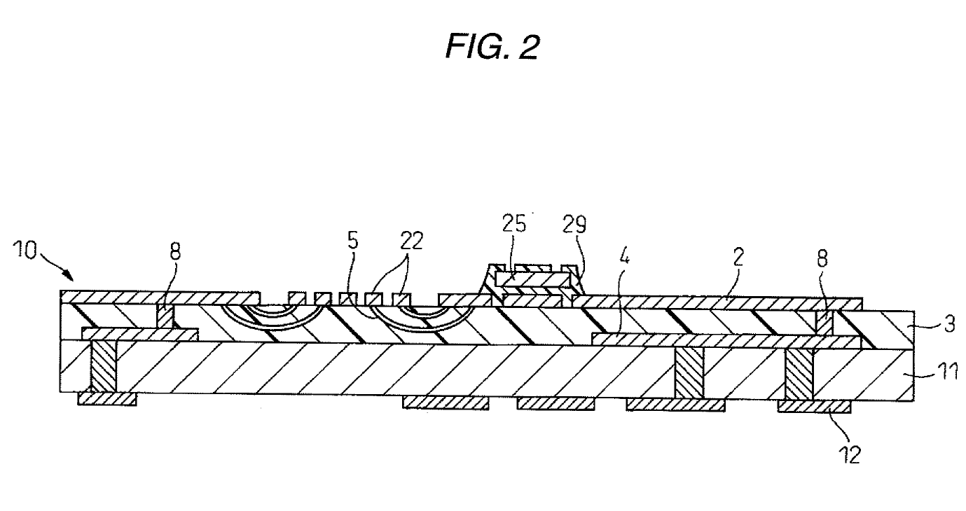

In a preferred embodiment, a multilayer wiring board 10 according to the invention has, as shown in FIG. 2, further chip parts 25 connected electrically to a first wiring layer 2. The multilayer wiring board 10 shown in FIG. 2 has basically the same structure as that of the multilayer wiring board 10 in FIG. 1, except that the multilayer wiring board shown in FIG. 2 has further the chip parts 25. The chip parts, though they are a capacitor, a register, an inductor, and the like, are not limited to theses parts. Further, in place of these chip parts, other functional parts may be built in the multilayer wiring board 10. Further, when the chip parts are connected to the first wiring layer 2, it is preferable that the chip parts 25 have been mounted on a metal foil 1 (wiring layer 2), and thereafter the surroundings of the chip parts 25 are filled with insulating organic resin material by potting, thereby to seal the chip parts 25 with the resin. Further, in this method, before or after the connection of the chip parts to the wiring layer, as shown in FIG. 2, at the periphery of the connection portion, a coating may be formed by a dam 29 formed of insulating material such as silicon resin or modified epoxy resin. By a dam effect, it is possible to prevent the solder from spreading. Further, of the coating to be formed, a portion to be wetted by solder is opened in advance, whereby necessary wetting can be secured.

As another aspect of the invention, there is a semiconductor device. The semiconductor device of the invention is characterized by including the multilayer wiring board of the invention, and an electronic part such as a semiconductor element mounted on an electronic part mounting capture pad of the multilayer wiring board such as a flip-chip capture pad. The semiconductor element to be mounted onto the flip-chip capture pad is not particularly limited, but can include various semiconductor chips such as an IC chip, an LSI chip, and the like. Further, in flip-chip mounting used for mounting of such the semiconductor chip, the flip-chip capture pad used as a mount is formed by the ordinary method, and the flip-chip mounting can be executed. The number of the electronic parts to be mounted on the multilayer wiring board may be one, or two and more. Further, in case that the plural electronic parts are mounted, their electronic parts may be the same or different. Further, on the flip-chip mounting surface of the multilayer wiring board, in addition to the flip-chip capture pad, a wiring layer and an external connection terminal (connection pad) may be formed. Further, on the opposite surface to the flip-chip mounting surface of the multilayer wiring board, in order to connect a mother board and other external parts to its opposite surface, a bump, for example, a solder bump or a land may be provided. In addition, in the semiconductor device of the invention, chip parts may be further built.

FIG. 3 is a sectional view showing a preferred embodiment of the semiconductor device according to the invention. A shown semiconductor device 50 shows an example in which a semiconductor chip 20 is mounted on the multilayer wiring board 10 shown in FIG. 1 by flip-chip mounting. The semiconductor chip 20 is mounted through bumps 21 formed on the lower surface of the semiconductor chip 20 on flip-chip capture pads (connection pads) 22 on the multilayer wiring board 10. Further, on the same surface as the semiconductor element mounting surface, a first wiring layer 2 is provided, and a solder resist layer 17 is provided on the first wiring layer 2. Further, another external connection terminal may be provided, which is not shown, thereby to connect an external device thereto. Further, the bump 21 portion of the semiconductor chip 20 may be sealed by underfill material. Further, a mother board 16 has bumps 13, and the multilayer wiring board 10 having a solder resist layer 18 on its lower surface is connected through its connection pads (conductor pads) 12 to the bumps 13. Each bump 13 is formed by, for example, a solder bump (SnAg).

In the semiconductor device 50, a conductor wire 5 which connects electrically the flip-chip capture pad 22 and the wiring layer 2 can have the aforesaid constitution. For example, the conductor wire 5, as described before referring to FIGS. 7(A) to 7(D), has the coaxial structure, whereby it is possible to prevent or reduce lowering of conductor loss and crosstalk. Further, the conductor wire 5 may connect a conductive metal layer of its uppermost layer to ground potential, which is not shown.

As another aspect of the invention, there is a manufacturing method of a multilayer wiring board of the invention. The multilayer wiring board of the invention can be manufactured in accordance with various methods or combination of various steps. The multilayer wiring board of the invention can be advantageously manufactured by, for example, the following steps of:

(a) preparing a metal foil for forming an electronic part mounting capture pad and a first wiring layer;

(b) wire-bonding, by a conductor wire, a portion of the metal foil which forms a pad in a later step, and a portion of the metal foil which forms a first connection part of the first wiring layer in a later step;

(c) applying a fluid organic insulating material onto the metal foil with thickness enough to cover the metal foil and the conductor wire throughout the entire surface of them, and hardening the fluid organic insulating material to form a first insulating layer; and

(d) etching the metal foil to form a pad, first and second connection parts, and a wiring pattern, and connecting linearly or curvedly, in this time, the first connection part and the second connection part through a first wiring pattern formed on the first wiring layer.

Further, according to the invention, by adding a step of mounting electronic parts to the last of each step in such the manufacturing method of the multilayer wiring board, it is also possible to provide a manufacturing method of a semiconductor device of the invention.

The above-mentioned manufacturing method of the multilayer wiring board can be variously improved within a scope of the invention. For example, the method of the invention can further include a step of aligning the metal foil with the base board of the multilayer wiring board having the plural wiring layers so that a first insulating layer of the metal foil is opposed to a second wiring layer on the base board, and laminating the metal foil on the base board.

Further, in the method of the invention, after the lamination step and before the etching step of the metal foil, an opening portion is formed in a portion of the metal foil where a vertical wiring part for connecting a second connection part of a second wiring layer and the second connection part of the first wiring layer is to be formed, thereafter the first insulating layer exposed in the opening portion is selectively etched with the metal foil having the opening portion as a mask, thereby to form a through-hole extending to the second wiring layer on the base board. Next, the through-hole is filled with conductive metal, whereby a vertical wiring part for connecting the second connection part of the metal foil and the second connection part of the second wiring layer can be formed.

Further, in the method of the invention, various conductor wires can be used in the wire bonding step (b). For example, as the conductor wire, there can be used a conductor wire formed of a wire rod of conductive metal; a conductor wire formed of a wire rod of conductive metal and an insulating coated layer with which the outer periphery surface of the wire rod is coated; or a conductor wire formed of a wire rod of conductive metal, and an insulating coated layer and a conductive layer with which the outer periphery surface of the wire rod is sequentially coated. The details of these conductor wires are as described before. Here, in a step of forming the coaxial structure in which the conductor wire is used as a core, it is preferable that the conductor layer is formed by an electroless plating method with conductive metal or a metal compound thermal decomposition method.

Further, the method of the invention may include a step of forming a third wiring layer on the first insulating layer, and a step of laminating a second insulating layer on the third wiring layer. Furthermore, such the method may include a step of forming an insulating resin layer between the first insulating layer and the third wiring layer.

Furthermore, the method of the invention may include a step of connecting a chip part to the metal foil before or after the bonding step (b). In this embodiment, it is preferable that the chip part is connected after an insulating material layer portion formed of silicon resin has been formed in the shape of a dam at the peripheral edge of a connection portion of the chip part. This is because such the constitution can prevent drip and spread of the solder.

FIGS. 6(A) to 6(G) show sectional views showing a preferable method of manufacturing the multilayer wiring board of invention. A multilayer wiring board to be manufactured here is the multilayer wiring board as described before with reference to FIGS. 1 and 4.

Firstly, as shown in FIG. 6(A), a metal foil 1 for forming a flip-chip capture pad, a first wiring layer (wiring pattern), and first and second connection parts in the later etching step is prepared. The metal foil 1, as described before, can be formed from copper or other conductive metals. In order to perform the alignment work in the later step accurately and quickly, it is recommended that an alignment mark is previously formed in the metal foil 1.

Next, as shown in FIG. 6(B), wire-bonding is performed, and two points on the metal foil 1 are connected through the conductor wire 5. In this wire-bonding step, a portion of the metal foil 1 where a flip-chip capture pad is to be formed, and a portion of the metal foil 1 where a first connection part is to be formed are connected through the conductor wire 5. The conductor wire 5 can be arranged curvedly and in three dimensions thereby to realize reduction of a wiring length.

More specifically, in the wire-bonding step, at the portions of the metal foil 1 where the flip-chip capture pad and the connection part are to be formed in the later step, the conductor wire 5 such as a gold wire is arranged thereby to connect electrically the flip-chip capture pad and the first connection part of the first wiring layer. As connection means, generally wire-bonding technology can be used. The conductor wire 5 can have a diameter of, for example, 20 μm. Though the conductor wire 5 can be thus used in non-coaxial structure, it can be used in coaxial structure according to necessity. The use of the conductor wire having the coaxial structure can reduce crosstalk and realize low EMI (electromagnetic interference).

In case that the conductor wire 5 is used in the form of the conductor wire having the coaxial structure, the conductor wire 5 having the coaxial structure can be formed as shown sequentially in FIGS. 7 (A) to 7 (D). Firstly, as shown in FIG. 7 (A), both ends of the conductor wire 5 are connected to the metal foil 1. Though only one end of the conductor wire 5 is shown in the figure, one end of the conductor wire 5 is connected to the flip-chip capture pad forming portion and the other end thereof is connected to the first connection part forming portion of the first wiring layer.

Next, as shown in FIG. 7(B), the surface of the conductor wire 5 connected to the metal foil 1, and the area in which the conductor wire 5 and the flip-chip capture pad forming portion are connected are coated with insulating material thereby to form an insulating coated layer 14. As the used insulating materials, there are, for example, epoxy resin, polyimide resin, and the like.

Thereafter, as shown in FIG. 7 (C), the insulating coated layer 14 is coated with conductive metal thereby to form a conductive metal layer 15. As the conductive metal, there are copper, chrome, and the like. The conductive metal layer 15 can be formed by, for example, an electroless plating method with conductive metal or a metal compound thermal decomposition method. Further, it is preferable that the conductive metal layer 15 connects electrically to the ground potential in order to realize the low EMI. Thus, as shown in FIG. 7(D) which is a sectional view taken along a line D-D of FIG. 7(C), a conductor wire having the coaxial structure of which a core is the conductor wire 5 can be formed.

After completion of the wire-bonding, it is a general order to apply fluid organic insulating material onto the metal foil 1 on which the conductor wire 5 is spatially arranged thereby to form an insulating layer. However, in the embodiment of the invention, according to the manufacturing process, another step can be performed prior to the formation of this insulating layer. For example, in case that a metal pillar functioning as a conductor portion is used in place of the vertical wiring part formed by plating, the metal pillar may be installed upright on the metal foil sequentially to the wire bonding step.

Sequentially, as shown in FIG. 6 (C), an insulating layer 3 referred to as a first insulating layer in the invention is formed on the metal foil 1. In the formation of the insulating layer 3, a method of applying fluid organic insulating resin material onto the metal foil 1 and thereafter hardening the resin material can be advantageously used. As the organic insulating resin material, from a viewpoint of the alleviation of stress, resin material having low elastic modulus such as silicon resin or modified epoxy resin can be advantageously used. The enough amount of organic insulating resin material to cover the entire surface of the metal foil 1 and the conductor wire 5 is applied. As the organic insulating resin material, for example, the silicon resin is applied by potting, and it can be hardened by keeping its temperature at 50˜100° C.

After the insulating layer has been formed on the metal foil, the metal foil is laminated on a base board of the multilayer wiring board prepared separately. In this lamination step, as shown in FIG. 6(D), the insulating layer 3 is inverted, whereby it is faced down and the metal foil 1 is faced up. Thereafter, the insulating layer 3 is aligned with the base board 11 of the multilayer wiring board and laminated thereon. Though the used base board 11 has two-layer structure, the invention is not limited to this. On the upper surface of the base board 11, a wiring layer 4 referred to as a second wiring layer in the invention has been already formed in a pattern. Further, on the lower surface of the base board 11, a connection pad 12 used when the multilayer wiring board is mounted on a mother board has been formed. In result of this lamination, the insulating layer 3 holding the metal foil 1 is opposed to the wiring layer holding surface of the base board 11, and they can be integrated. In this lamination, for example, an adhesive such as an adhesive tape can be used between the base board 11 and the insulating layer 3.

In execution of the method of the invention, before the lamination of the base board 11 and the metal foil 1 including the insulating layer (first insulating layer) 3, a third wiring layer 34 may be formed on the first insulating layer 3 as shown in FIG. 6(C′), and a second insulating layer 33 may be further laminated on its third wiring layer 34 as shown in FIG. 6(C″). The formation of the third wiring layer 34 and the second insulating layer 33 can be performed by the similar method to the method of forming another insulating layer and another wiring layer which has been described in this specification. Further, between the first insulating layer 3 and the third wiring layer 34, an insulating resin layer, which is not shown, may be further formed of arbitrary material.

After the base board 11 and the metal foil 1 including the insulating layer 3 have been laminated, as shown in FIG. 6(E), a vertical wiring part 8 is formed from conductive metal, which connects a portion of the metal foil 1 where a second connection part is to be formed in a later step and a second portion of the second wiring layer 4 on the base board 11, and penetrates the first insulating layer 3.

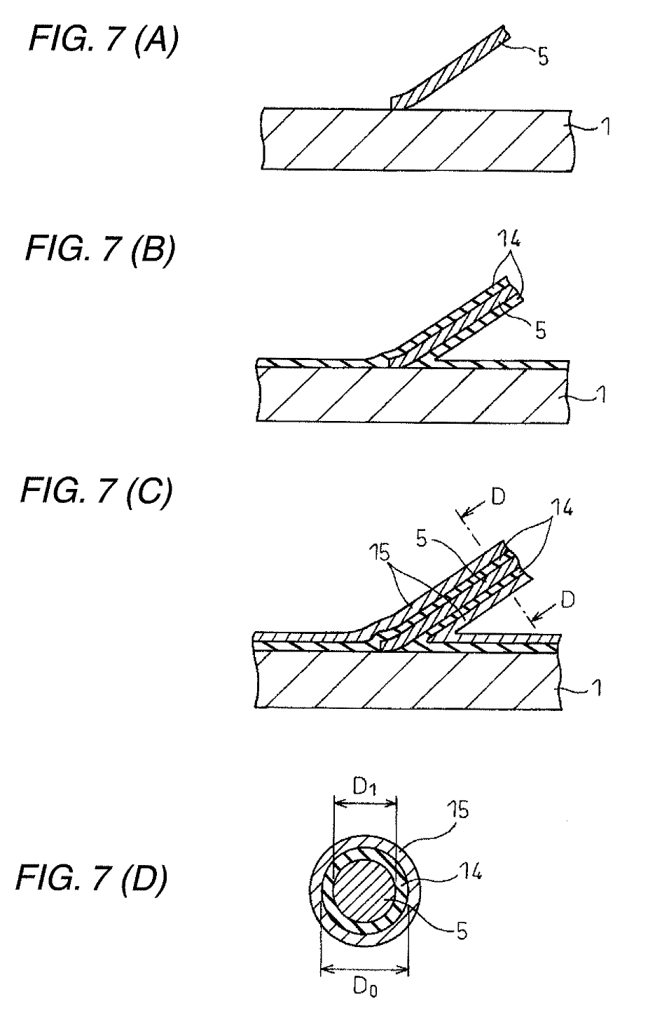

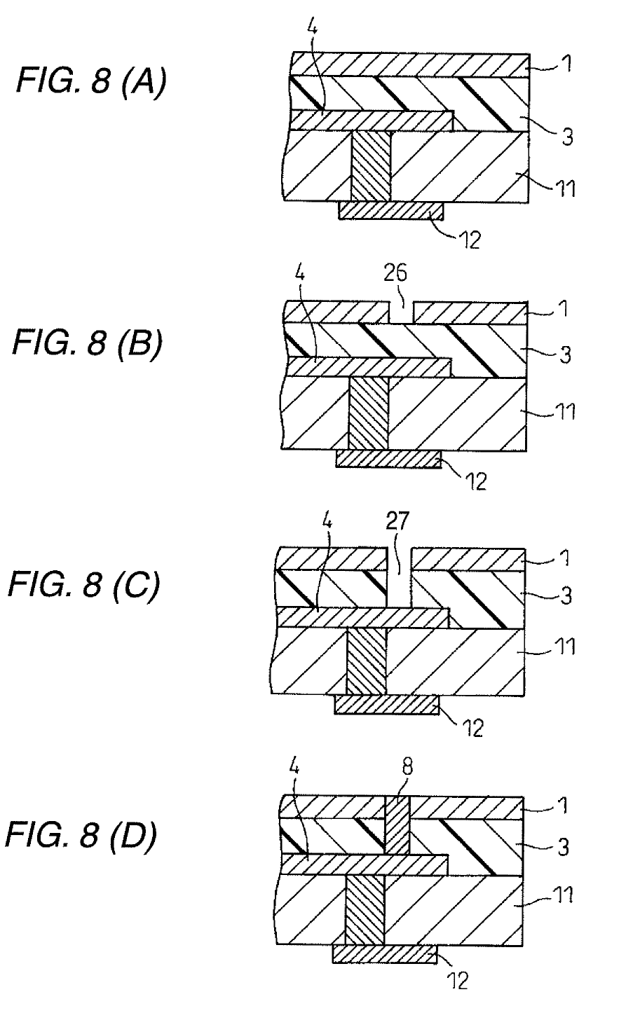

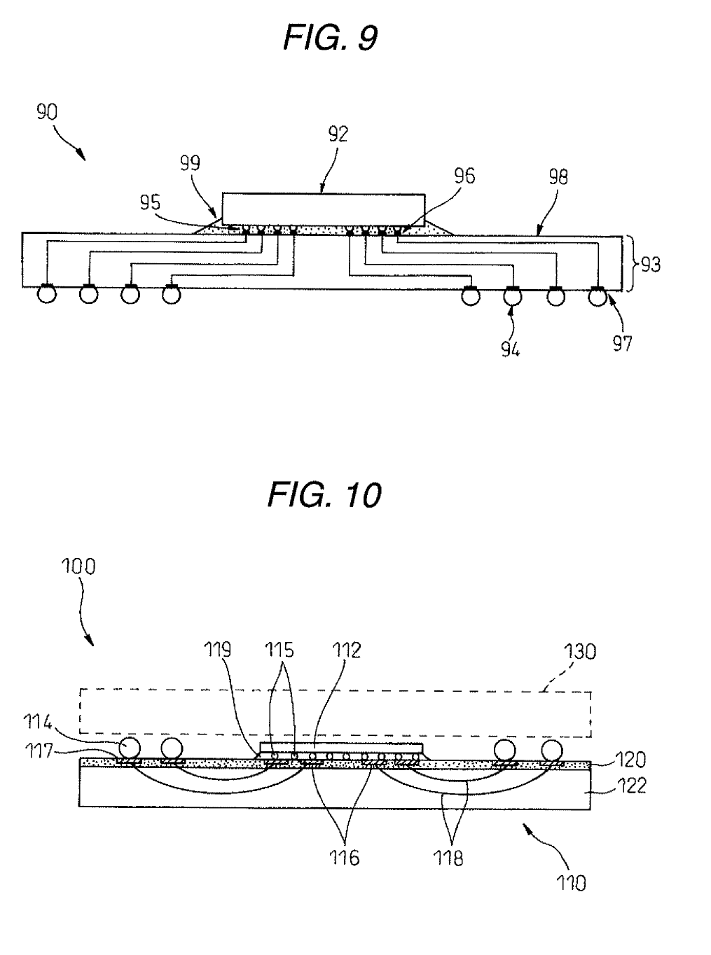

The formation of the vertical wiring part 8 can be formed by, for example, a method shown in FIGS. 8(A) to 8(D) in due order. As understood from the figure, FIG. 8(A) shows a part of the multilayer wiring board 10 described before referring to FIG. 6(D).

Firstly, after the wire bonding step and before a patterning step of the metal foil 1, as shown in FIG. 8 (B), an opening portion 26 is formed, in the metal foil 1, at a portion corresponding to the second connection part (refer to a reference number 2-2 in FIG. 4) of the first wiring layer of the multilayer wiring board. The opening portion 26 is a portion under which the vertical wiring part 8 will be formed in a later step. The opening portion 26 can be readily formed, for example, by forming an etching resist layer (not shown) on the metal foil 1 and thereafter selectively removing the portion of the metal foil 1 corresponding to the vertical wiring part by etching.

Next, as shown in FIG. 8 (C), with the etching resist layer and the metal foil 1 thereunder as a mask, the insulating layer 3 exposed at the opening portion 26 is selectively etched, thereby to form a through-hole 27 extending to the second wiring layer 4 of the base board 11. Of the wiring layer 4, an end portion of this etching is referred to as the second connection part in the invention. As shown in the figure, the through-hole 27 extending from the metal foil 1 to the second wiring layer 4 is obtained.

After the formation of the through-hole, as shown in FIG. 8(D), the through-hole 27 is filled with conductive metal, thereby to form the vertical wiring part 8 which connects the metal foil 1 and the second wiring layer 4 of the base board 11. The formation of the vertical wiring part 8 can be achieved by executing plating with conductive metals, for example, applying electroless copper plating and electrolytic copper plating in order onto the entire surface of the metal foil 1. By such the conductive metal plating, the through-hole 27 and the opening portion of the metal foil 1 formed on the through-hole 27 can be filled with the conductive metal. After completion of the plating, the etching resist layer remaining on the uppermost layer is removed.

After the vertical wiring part has been thus formed, as shown in FIG. 6(F), the metal foil 1 is subjected to selective patterning in the desired wiring pattern. The patterning can be performed preferably by etching. The etching of the metal foil 1 can be formed by an ordinary method using an appropriate etchant according to the kind of the metal foil. For example, in case that the metal foil 1 is a copper foil, ferric chloride or the like can be used as the etchant. In result of the etching, flip-chip capture pads 22 and a wiring layer 2 having the desired wiring pattern (combination of the first wiring part 2-1, the first wiring layer 2 and the second wiring part 2-2 as shown in FIG. 4) are obtained. By such a series of steps, the multilayer wiring board 10 of the invention is obtained.

In the method of the invention, further sequentially, a solder resist layer can be provided on the multilayer wiring board 10. For example, as shown in FIG. 6(G), onto the conductor pads 12 provided on the lower surface of the base board 11, solder balls 13 can be attached. Alternatively, bumps 13 may be formed on the lower surface of the base board 11, and solder resist layers 17 and 18 may be formed on outermost surfaces. On the solder resist layer 17, a chip part may be mounted.

### EXAMPLES

Sequentially, the invention will be described with reference to examples thereof. The invention is not limited to the following examples.

### Example 1

A copper foil (size: about 15 cm square) on which alignment marks are formed and a multilayer wiring board (base board) having two-layer structure are prepared. A flip-chip capture pad forming portion and a portion forming a first connection part of a first wiring layer are connected by a gold wire having a diameter of 25 μm. Next, in order to form an insulating layer, silicon resin having low elastic modulus is supplied by potting so as to cover the entire surfaces of the copper foil and the gold wire, and is kept at 50˜100° C. to be hardened. Hereby, the insulating layer (thickness: about μm on the copper foil) with which the gold wire is fully covered is obtained. After the formation of the insulating layer, the metal foil is laminated on the base board prepared separately so that the insulating layer on the copper foil is opposed to a wiring layer holding surface of the base board. In order to join the copper foil to the base board, an epoxy adhesive is used.

Next, a vertical wiring part is formed, which penetrated the insulating layer formed on the copper foil, and connected a connection part of a wiring layer to be formed from the copper foil and a wiring part of a wiring layer on the base board. In order to form the vertical wiring part, firstly, a through-hole penetrating a connection part forming portion on the copper foil and the insulating layer thereunder is formed. In case of this example, a through-hole having a diameter of about 80 μm is formed by CO₂ laser. Next, by applying electroless copper plating and electrolytic copper plating onto the copper foil, the through-hole is filled with the copper.

After the formation of the vertical wiring part, etching of the copper foil is performed by means of an etchant of ferric chloride, whereby flip-chip capture pads and a wiring layer are formed. In the obtained multilayer wiring board, the flip-chip capture pad and the first connection part of the wiring layer are wire-bonded through the gold wire, and the wiring layer is formed in a wiring pattern in which its first connection part and its second wiring part are connected. After completion of etching, a solder resist is applied on the outermost surfaces with a thickness of about 20 μm. In the multilayer wiring board in this example, compared with the conventional multilayer wiring board, conductor loss and crosstalk can be reduced. This multilayer wiring board may be, according to necessity, subjected to plating such as nickel plating, gold plating, solder plating, or the like.

### Example 2

By the method described in the example 1, the multilayer wiring board is manufactured. In this example, in place of the gold wire, the following wires are used:

(1) copper wire

(2) aluminum wire

(3) gold wire having the coaxial structure in which a gold wire is coated in order with an insulating resin layer of a silicon resin and a conductor layer of copper.

In these cases, similarly to the case of the multilayer wiring board in the example 1, the conductor loss and the crosstalk can be reduced.

What is claimed is:

1. A multilayer wiring board comprising:
two or more layers of wiring layers and insulating layers alternately laminated, wherein
a group of electronic part mounting capture pads are provided on one surface of the multilayer wiring board;
a first wiring layer formed on an uppermost layer of the multilayer wiring board includes a first connection part arranged on the same surface as the surface where the pads are provided, and a second connection part spaced from the first connection part;
the pad and the first connection part are electrically connected through a conductor wire, the conductor wire being provided in a first insulating layer laminated on the first wiring layer; and
the first connection part is connected linearly or curvedly to the second connection part through a first wiring pattern formed on the first wiring layer.

2. The multilayer wiring board according to claim 1, wherein
the second connection part is connected, through a vertical wiring part provided with penetrating the first insulating layer, to a second connection part of a second wiring layer formed under the first insulating layer.

3. The multilayer wiring board according to claim 1, wherein
the insulating layer is formed of organic resin material having low dielectric constant.

4. The multilayer wiring board according to claim 1, wherein
the conductor wire is formed of a wire rod of conductive metal; formed of a wire rod of conductive metal and an insulating coated layer with which the outer periphery surface of the wire rod is coated; or formed of a wire rod of conductive metal, an insulating coated layer and a conductive layer with which the outer periphery surface of the wire rod is sequentially coated.

5. A method of manufacturing the multilayer wiring board according to claim 1, comprising the steps of:
preparing a metal foil for forming the electronic part mounting capture pads and the first wiring layer;
wire-bonding, by a conductor wire, a portion of the metal foil which forms the pad in a later step, and a portion of the metal foil which forms the first connection part of the first wiring layer in a later step;
applying a fluid organic insulating material onto the metal foil with thickness enough to cover the metal foil and the conductor wire throughout the entire surface thereof, and hardening the fluid organic insulating material to form a first insulating layer; and
etching the metal foil to form the pad, the first and second connection parts, and the first wiring pattern, and connecting linearly or curvedly, in this time, the first connection part and the second connection part through the first wiring pattern.

6. The manufacturing method according to claim 5, further comprising:
a step of aligning the metal foil with a base board of the multilayer wiring board having plural wiring layers so that the first insulating layer of the metal foil is opposed to a second wiring layer on the base board, and laminating the metal foil on the base board.

7. The manufacturing method according to claim 6, wherein
after the lamination step and before etching of the metal foil, an opening portion is formed in a portion of the metal foil where the second connection part of the first wiring layer is formed;
with the metal foil as a mask, the first insulating layer exposed at the opening portion is selectively etched to form a through-hole extending to the second wiring layer on the base board; and
the through-hole is filled with conductive metal, to form the vertical wiring part for connecting the second connection part of the first wiring layer and the second connection part of the second wiring layer.

8. The manufacturing method according to claim 5, further comprising the steps of:
forming a third wiring layer on the first insulating layer; and
laminating a second insulating layer on the third wiring layer.

9. The manufacturing method according to claim 8, further comprising:
a step of forming an insulating resin layer between the first insulating layer and the third wiring layer.

10. A semiconductor device comprising:
the multilayer wiring board according to claim 1, and
electronic parts mounted on the electronic part mounting capture pads of the multilayer wiring board.
